(19) United States
(12) Patent Application Publication
(10) Pub. No.: US 2013/0312993 A1
(43) Pub. Date: Nov. 28, 2013

(54) CABLE STRUCTURE

(71) Applicant: Ho-Man Rodney Chiu, Sunnyvale, CA (US)

(72) Inventor: Ho-Man Rodney Chiu, Sunnyvale, CA (US)

(21) Appl. No.: 13/481,794

(22) Filed: May 26, 2012

(51) Int. Cl. H05K 9/00

(52) U.S. Cl. 174/34

(57) ABSTRACT

A cable structure includes a conductor, a shielding layer wrapping the conductor, a knit layer surrounding the shielding layer, an absorbing layer enclosing the knit layer and made of efficient absorbing materials, and an insulating layer bounding round the absorbing layer. In use, the shielding layer and the knit layer shield electromagnetic waves produced by the conductor from diffusing outward and further shield outside electromagnetic waves from diffusing inward. The absorbing layer is capable of absorbing the electromagnetic waves which fail to be shielded by the shielding layer and the knit layer.

### BACKGROUND OF THE INVENTION

1. Field of the Invention

The present invention relates to a cable structure, and more particularly to a cable structure capable of filtering the electromagnetic waves.

2. The Related Art

Cables are mainly used to connect between two electronic devices for electric and optical transmission. A traditional cable structure includes a conductor, a shielding layer wrapping the conductor, a knit layer surrounding the shielding layer, and an insulating layer bounding round the knit layer. The shielding layer is used for shielding electromagnetic waves produced by the conductor in use from diffusing outward, and further shielding outside electromagnetic waves from interfering the signal transmission of the conductor. However, in actual use, there are always a few electromagnetic waves diffusing through the shielding layer outward and inward to interfere the signal transmission of the conductor of the cable structure.

### SUMMARY OF THE INVENTION

An object of the present invention is to provide a cable structure. The cable structure includes a conductor, a shielding layer wrapping the conductor, a knit layer surrounding the shielding layer, an absorbing layer enclosing the knit layer and made of efficient absorbing materials, and an insulating layer bounding round the absorbing layer. Wherein the shielding layer and the knit layer shield electromagnetic waves produced by the conductor from diffusing outward and further shield outside electromagnetic waves from diffusing inward, and the absorbing layer is capable of absorbing the electromagnetic waves which fail to be shielded by the shielding layer and the knit layer.

As described above, the cable structure utilizes the absorbing layer made of efficient absorbing materials to filter and absorb the electromagnetic waves which fail to be shielded by the shielding layer and the knit layer. So, the signals can be effectively transmitted by the conductor almost without electromagnetic interference.

### BRIEF DESCRIPTION OF THE DRAWINGS

The present invention will be apparent to those skilled in the art by reading the following description, with reference to the attached drawing, in which:

FIG. 1 is a cross-sectional view of a cable structure in accordance with an embodiment of the present invention.

### DETAILED DESCRIPTION OF THE PREFERRED EMBODIMENT

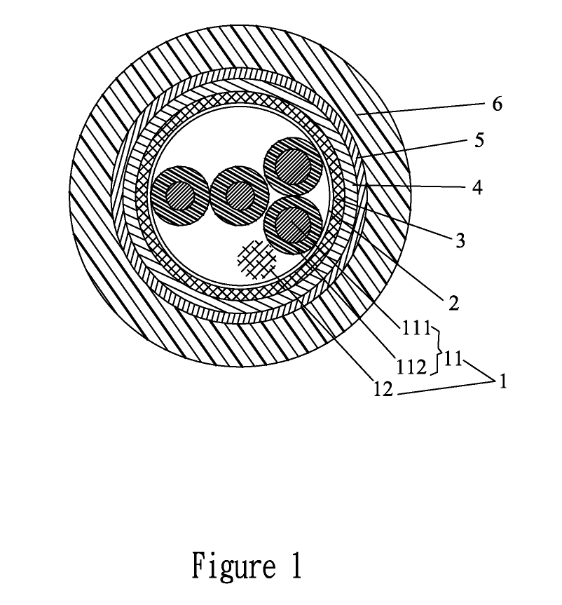

Referring to FIG. 1, a cable structure according to an embodiment of the present invention is shown. The cable structure includes a conductor 1, a shielding layer 2 wrapping the conductor 1, a knit layer 3 surrounding the shielding layer 2, an absorbing layer 4 enclosing the knit layer 3, an isolating layer 5 bounding round the absorbing layer 4, and an insulating layer 6 wrapping the isolating layer 5.

Referring to FIG. 1, the conductor 1 includes at least one conducting wire 11 and at least one filling wire 12 entwined together with the conducting wire 11. In this embodiment, the cable structure is used to connect with a USB2.0 connector, so there are four conducting wires 11 and the conducting wires 11 are tin-plated copper wires. The conducting wire 11 further includes a core wire 111 and an insulating cover 112 surrounding the core wire 111. The filling wire 12 is employed for filling the space between the conducting wire 11 and the shielding layer 2 to make the conductor 1 show a cylindrical shape for the convenience of wrapping the layers of the cable structure. The shielding layer 2 wrapping the conductor 1 is made of aluminum materials.

The knit layer 3 surrounding the shielding layer 2 is interlaced by multiple knitting wires (not shown). Each of the knitting wires has a plurality of metallic wires (not shown) which are arranged side by side to form a metallic strip (not shown), and at least one fiber filament (not shown) arranged at an outer side of the metallic strip. The abreast knitting wires are arranged by means of each two adjacent metallic strips sandwiching at least one fiber filament therebetween. In this embodiment, the metallic wire is a tin-plated copper wire or a copper-plated aluminum wire, and the fiber filament is a ballistic filament or a nylon filament.

The absorbing layer 4 enclosing the knit layer 3 is made of efficient absorbing materials. In use, the shielding layer 2 and the knit layer 3 shield electromagnetic waves produced by the conductor 1 from diffusing outward to interfere exterior electronic devices, and further shield outside electromagnetic waves from diffusing inward to interfere signal transmission of the conductor 1. The absorbing layer 4 is employed for filtering and absorbing the electromagnetic waves which fail to be shielded by the shielding layer 2 and the knit layer 3 to further ensure the signal transmission of the conductor 1.

The isolating layer 5 surrounds the absorbing layer 4 and is located between the absorbing layer 4 and the insulating layer 6 for the convenience of peeling the insulating layer 6 without damaging the absorbing layer 4.

As described above, the cable structure utilizes the absorbing layer 4 made of efficient absorbing materials to filter and absorb the electromagnetic waves which fail to be shielded by the shielding layer 2 and the knit layer 3. So, the signals can be effectively transmitted by the conductor 1 almost without electromagnetic interference.

What is claimed is:

1. A cable structure, comprising:
a conductor;
a shielding layer wrapping the conductor;
a knit layer surrounding the shielding layer;
an absorbing layer enclosing the knit layer and made of efficient absorbing materials; and
an insulating layer bounding round the absorbing layer,
wherein the shielding layer and the knit layer shield electromagnetic waves produced by the conductor from diffusing outward and further shield outside electromagnetic waves from diffusing inward, the absorbing layer is capable of absorbing the electromagnetic waves which fail to be shielded by the shielding layer and the knit layer.

2. The cable structure as claimed in claim 1, wherein the knit layer is interlaced by multiple knitting wires, each of the knitting wires has a plurality of metallic wires which are arranged side by side to form a metallic strip, and at least one fiber filament arranged at an outer side of the metallic strip, the abreast knitting wires are arranged by means of each two adjacent metallic strips sandwiching at least one fiber filament therebetween.

3. The cable structure as claimed in claim 2, wherein the metallic wire is a tin-plated copper wire or a copper-plated aluminum wire.

4. The cable structure as claimed in claim 2, wherein the fiber filament is a ballistic filament or a nylon filament.

5. The cable structure as claimed in claim 1, wherein the conductor includes at least one conducting wire and at least one filling wire entwined together with the conducting wire.

6. The cable structure as claimed in claim 5, wherein the conducting wire has a core wire and an insulating cover surrounding the core wire.

7. The cable structure as claimed in claim 1, wherein the shielding layer is made of aluminum materials.

8. The cable structure as claimed in claim 1, further comprising an isolating layer which surrounds the absorbing layer and is located between the absorbing layer and the insulating layer.
